(19) United States
(12) Patent Application Publication
(10) Pub. No.: US 2025/0347744 A1
(43) Pub. Date: Nov. 13, 2025

(54) CHARGE-DISCHARGE APPARATUS FOR RECHARGEABLE BATTERY

(71) Applicant: SAMSUNG SDI CO., LTD., Yongin-si (KR)

(72) Inventor: Hyunju KIM, Yongin-si (KR)

(21) Appl. No.: 19/005,385

(22) Filed: Dec. 30, 2024

(30) Foreign Application Priority Data
May 8, 2024 (KR) 10-2024-0060742

(51) Int. Cl. G01R 31/36; G01B 11/14; G01R 31/392; H01M 10/48

(52) U.S. Cl. CPC G01R 31/3644; G01B 11/14; G01R 31/392; H01M 10/486; H01M 10/488

(57) ABSTRACT

A charge-discharge apparatus for a rechargeable battery is disclosed. A charge-discharge apparatus for a rechargeable battery includes a base plate configured to have a battery cell affixed thereon, a charger-discharger on the base plate, and configured to charge the battery cell, a support part protruding from one side of the base plate, an elevating plate at the support part, and configured raise and lower, a distance-measuring part configured to measure a separation distance between the base plate and the elevating plate contacting the battery cell, a temperature-measuring part at a lower surface of the elevating plate, and configured to measure a temperature of the battery cell, and a display part configured to display the separation distance and the temperature.

### CROSS-REFERENCE TO RELATED APPLICATION

The present application claims priority to and the benefit of Korean Patent Application No. 10-2024-0060742, filed on May 8, 2024, in the Korean Intellectual Property Office, the entire disclosure of which is incorporated herein by reference.

### BACKGROUND

### 1. Field

The present disclosure relates to a charge-discharge apparatus for a rechargeable battery.

### 2. Description of the Related Art

In general, a charge-discharge apparatus for a rechargeable battery is widely used to evaluate the reliability and lifespan of battery cells by applying current to the terminals of the battery cells.

In such conventional charge-discharge apparatus for a rechargeable battery, if lifespan evaluation takes a long time, thickness measurement may be performed to check changes in the thickness of the battery cell.

Currently, the thickness measurement method for rechargeable batteries is to withdraw the battery cells from the charger-discharger by charging cycle, and the thickness is measured manually by the evaluator, which reduces the convenience of measuring the thickness of the battery cells, and does not facilitate the measurement of real-time thickness changes.

If it is suitable to measure the temperature of the battery cell during the evaluation of the battery cell, there are also a charger-discharger with a thermocouple (TC) installed, but there is a problem in that it is impossible to measure the temperature of the battery cell by position, because it is formed of a single wire, and attaching the TC wire to the surface of the battery cell may be cumbersome.

### SUMMARY

One or more embodiments of the present disclosure provide a charge-discharge apparatus for a rechargeable battery capable of measuring the thickness and temperature of a battery cell in real time by installing a thermocouple (TC) wire for temperature measurement on a plate for measuring the thickness of the battery cell.

One or more embodiments of the present disclosure includes a charge-discharge apparatus for a rechargeable battery including a base plate configured to have a battery cell affixed thereon, a charger-discharger on the base plate, and configured to charge the battery cell, a support part protruding from one side of the base plate, an elevating plate at the support part, and configured raise and lower, a distance-measuring part configured to measure a separation distance between the base plate and the elevating plate contacting the battery cell, a temperature-measuring part at a lower surface of the elevating plate, and configured to measure a temperature of the battery cell, and a display part configured to display the separation distance and the temperature.

The charge-discharge apparatus for the rechargeable battery may further include a guide rail configured to guide the elevating plate at a side surface of the support part.

The elevating plate may be detachably at the support part.

The charge-discharge apparatus for the rechargeable battery may further include a handle protruding from a side surface of the elevating plate.

The elevating plate may define an insertion groove for receiving the temperature-measuring part.

The insertion groove may include a mesh shape at the lower surface of the elevating plate.

The temperature-measuring part may include a thermocouple (TC) wire inserted into the lower surface of the elevating plate.

The temperature-measuring part may include a mesh shape.

The distance-measuring part may include a laser sensor between the elevating plate and the base plate.

The display part may include a receiver configured to receive a sensing signal from the distance-measuring part or the temperature-measuring part, and a display configured to display information corresponding to the sensing signal.

The display may include a distance display panel configured to display the separation distance.

The display may further include a temperature display panel configured to display the temperature of the battery cell.

The charge-discharge apparatus for the rechargeable battery may further include a distance display scale at a side surface of the support part.

The charge-discharge apparatus for the rechargeable battery may further include an indicator for indicating the distance display scale at a side surface of the elevating plate.

According to one or more embodiments of the present disclosure, a TC wire for temperature measurement, which may be installed on the surface where the battery cell, is in contact with the plate for measuring the thickness of the battery cell, and the temperature that changes may be measured in real time while measuring the thickness of the battery cell, so that evaluation of the reliability and lifespan of the battery cells may be performed more effectively.

### BRIEF DESCRIPTION OF THE DRAWINGS

FIG. 1 is a perspective view schematically showing a charge-discharge apparatus for a rechargeable battery according to first one or more embodiments of the present disclosure.

FIG. 2 is a perspective view schematically showing a state in which a guide rail may be installed on a support part of FIG. 1.

1 FIG. 3 is a perspective view schematically showing an elevating plate according to the first one or more embodiments of the present disclosure.

FIG. 4 is a side view schematically showing a state in which the battery cell according to the first one or more embodiments of the present disclosure is located between the base plate and the elevating plate.

FIG. 5 is a perspective view schematically showing a state in which a TC wire is separated from the elevating plate according to the first one or more embodiments of the present disclosure.

FIG. 6 is a perspective view schematically showing a display part installed on the support part according to the first one or more embodiments of the present disclosure.

FIG. 7 is a perspective view schematically showing a charge-discharge apparatus for a rechargeable battery according to second one or more embodiments of the present disclosure.

FIG. 8 is a perspective view schematically showing a charge-discharge apparatus for a rechargeable battery according to third one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

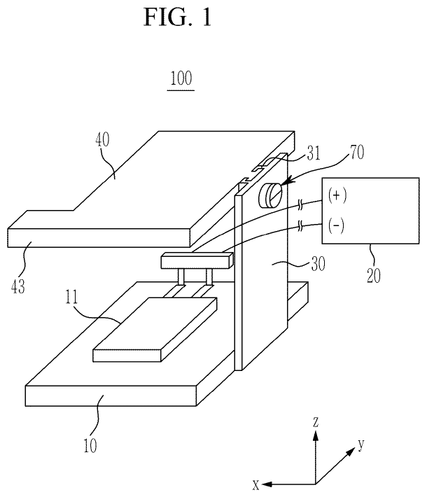

FIG. 1 is a perspective view schematically showing a charge-discharge apparatus for a rechargeable battery according to first one or more embodiments of the present disclosure. As described below, a charge-discharge apparatus for a rechargeable battery is capable of measuring the thickness and temperature of a battery cell in real time during the charge-discharge process of the battery cell.

As shown in FIG. 1, a charge-discharge apparatus for a rechargeable battery 100 according to first one or more embodiments of the present disclosure includes a base plate 10 on which a battery cell 11 is affixed, a charger-discharger 20 installed on the base plate 10 to charge the battery cell 11, a support part 30 protruding from one side of the base plate 10, an elevating plate 40 installed on the support part 30 to enable elevation, a distance-measuring part (e.g., a laser sensor) 50 that measures the separation distance between the base plate 10 and the elevating plate 40 (e.g., if the elevating plate 40 is in contact with the battery cell 11), a temperature-measuring part (e.g., a thermocouple (TC) wire) 60 installed on the lower surface of the elevating plate 40 to measure the temperature of the battery cell, and a display part 70 that displays the measured distance of the distance-measuring part 50 and the temperature measured by the temperature-measuring part 60.

The base plate 10 may be installed on the lower portion of the installation site, and a flat surface is formed at the top so that the battery cell 11 may be affixed.

The battery cell 11 may be affixed by being seated on the upper surface of the base plate 10, and may be affixed by a clamping device (e.g., a predetermined clamping device), in one or more embodiments.

The battery cell 11 may be charged by the charger-discharger 20 while being affixed to the base plate 10.

The charger-discharger 20 may be installed at a position close to the battery cell 11 on the base plate 10 to perform a charging operation of the battery cell 11. Because the configuration of the above charger-discharger 20 may be a known configuration, the detailed configuration and operation description thereof will be omitted.

The support part 30 may be installed on one side of the base plate 10. One side of the support part 30 may be affixed to the side surface of the base plate 10, and the other side of the support part 30 may protrude upwardly from the base plate 10.

The elevating plate 40 may be installed on the support part 30 to enable elevation.

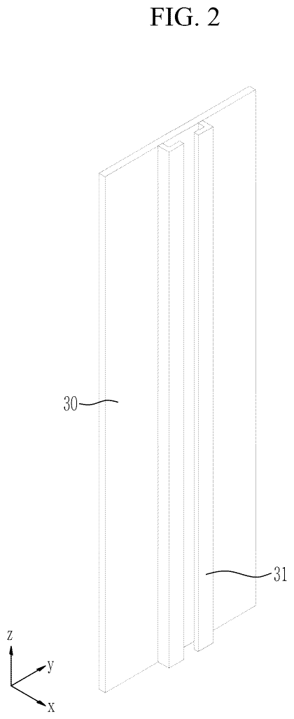

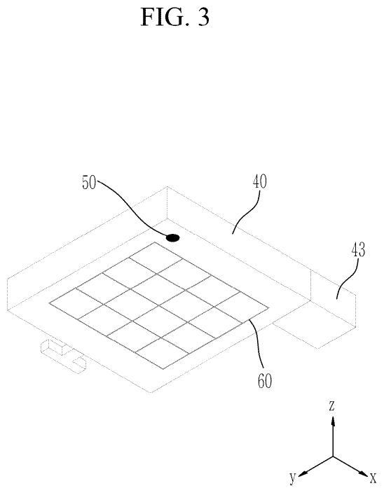

FIG. 2 is a perspective view schematically showing a state in which a guide rail may be installed on a support part of FIG. 1.

As shown in FIG. 2, a guide rail 31 for elevation operation of the elevating plate 40 may be installed on the support part 30. The guide rail 31 may be installed on the side surface of the support part 30 in a long vertical direction, and the elevating plate 40 may be installed to slide up and down. The guide rail 31 may be installed as a linear motion (LM) guide type, so that the elevating plate 40 may be lowered or raised to an appropriate height while being guided in the direction of the battery cell 11.

In one or more embodiments, the elevating plate 40 may be lowered from the support part 30 along the guide rail 31, and may be in contact with the battery cell 11. As shown in FIG. 1, a handle 43 may protrude from the side surface of the elevating plate 40 for an operator to grip by hand.

As such, the elevating plate 40 may be installed on the support part 30 to enable elevation so as to contact the surface of the battery cell 11 during the charging process of the battery cell 11, and to measure the changing thickness of the battery cell 11 in real time.

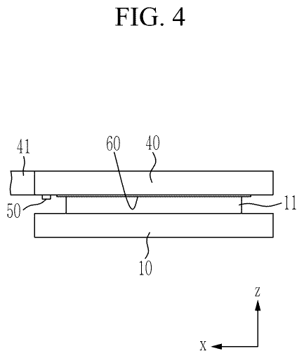

FIG. 3 is a perspective view schematically showing an elevating plate according to the first one or more embodiments of the present disclosure, and FIG. 4 is a side view schematically showing a state in which the battery cell according to the first one or more embodiments of the present disclosure is located between the base plate and the elevating plate.

As shown in FIGS. 3 and 4, the distance-measuring part 50 may be installed between the base plate 10 and the elevating plate 40.

The distance-measuring part 50 may be a distance-measuring part installed between the elevating plate 40 and the base plate 10. Hereinafter, the distance-measuring part and the distance-measuring part use the same reference number.

The distance-measuring part 50 may be installed on the lower surface of the elevating plate 40, and may measure the distance between the elevating plate 40 and the base plate 10.

In one or more embodiments, in a state in which the elevating plate 40 is lowered into contact with the surface of the battery cell 11, the distance between the elevating plate 40 and the base plate 10 is measured using the distance-measuring part 50, thereby enabling real-time measurement of the changing thickness of the battery cell 11 during the charging process of the battery cell 11.

In one or more embodiments, the thickness of the battery cell 11 changes in real time depending on the state of charge, and the elevation movement of the elevating plate 40 may be implemented in real time according to the change in the thickness of the battery cell 11.

It is possible to measure the distance between the elevating plate 40 and the base plate 10 using the distance-measuring part 50, and to sense the change in thickness of the battery cell 11 in real time.

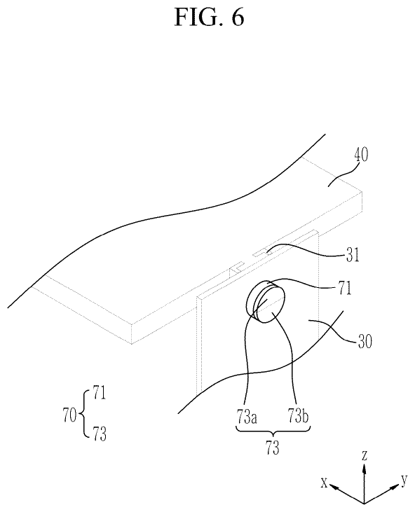

The sensing signal of the distance-measuring part 50 may be transmitted to the display part 70 shown in FIGS. 1 and 6.

The elevating plate 40 may also be detachably installed on the support part 30. Therefore, the elevating plate 40 may be replaced appropriately according to the weight or size in response to changes in the specifications of the battery cell 11, allowing for more effective evaluation of the lifespan and reliability of the battery cell 11.

In one or more embodiments, the temperature-measuring part 60 may be installed on the elevating plate 40. The temperature-measuring part 60 may be installed on the lower surface of the elevating plate 40 to measure the temperature of the battery cell 11 if the temperature-measuring part 60 is in contact with the battery cell 11 by lowering the elevating plate 40.

The temperature-measuring part 60 may be installed to contact the battery cell 11 while being inserted into the lower surface of the elevating plate 40 to enable real-time temperature measurement of the battery cell 11. The temperature-measuring part 60 may be a thermocouple (TC) wire inserted into the interior.

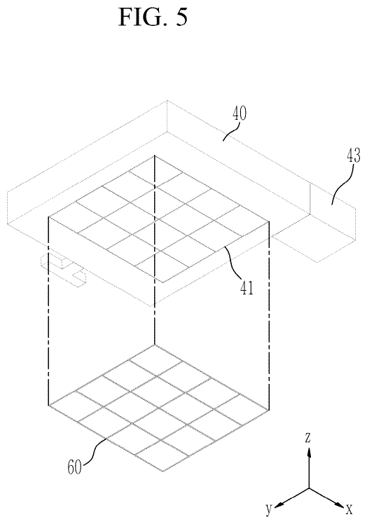

FIG. 5 is a perspective view schematically showing a state in which a temperature-measuring part is separated from the elevating plate according to the first one or more embodiments of the present disclosure.

As shown in FIG. 5, the temperature-measuring part 60 is partially inserted into the interior of the elevating plate 40 and partially exposed to the lower surface of the elevating plate 40, allowing for real-time measurement of the battery cell 11.

The temperature-measuring part 60 may be installed on the lower surface of the elevating plate 40 in a mesh shape. For this purpose, an insertion groove 41 corresponding to the mesh shape of the temperature-measuring part 60 may be formed in the elevating plate 40. In one or more embodiments, the insertion groove 41 may be formed in a mesh shape corresponding to the mesh shape of the temperature-measuring part 60.

The temperature of the battery cell 11, which is measured by the temperature-measuring part 60, may be transmitted to the display part 70. The display part 70 may receive sensing signals from the temperature-measuring part 60 and the distance-measuring part 50, and may display the sensing signals for visual confirmation by a user.

FIG. 6 is a perspective view of the main part schematically showing a display part installed on the support part according to the first one or more embodiments of the present disclosure.

Referring to FIG. 6, the display part 70 may include a receiver 71 that receives a sensing signal from the distance-measuring part 50 and the temperature-measuring part 60, and a display 73 installed in the receiver 71 to display the sensing signal.

The receiver 71 may protrude at the side surface of the support part 30, and may be installed to receive the sensing signal from the distance-measuring part 50 or the temperature-measuring part 60. The receiver 71 may be illustrated as protruding from the side surface of the support part 30, but is not necessarily limited thereto, and may also be installed and inserted into the interior of the support part 30. The receiver 71 may protrude from the side surface of the support part 30 in a round shape, or may protrude in a shape (e.g., predetermined shape) such as a polygonal shape.

The display part 70 may be installed in the receiver 71. The display part 70 may be installed on the protruding surface of the receiver 71, and may be installed to display a sensing signal sensed by the distance-measuring part 50 or the temperature-measuring part 60.

In one or more embodiments, the display part 70 may include a distance display panel 73a that displays the distance between the elevating plate 40 and the base plate 10, and a temperature display panel 73b that displays the temperature measured by the temperature-measuring part 60. The distance display panel 73a and the temperature display panel 73b may be installed on the surface of the receiver 71, and may be installed as a display type capable of digital display so that the operator can visually check the distance display panel 73a and the temperature display panel 73b. The distance display panel 73a and the temperature display panel 73b may enable operation controls using a push-button type or a touch type.

In one or more embodiments, the operator may easily visually check the information displayed in the digital state of the display part 70, and may easily check the thickness of the battery cell 11 located between the elevating plate 40 and the base plate 10, and the real-time changed temperature of the battery cell 11 by the temperature-measuring part 60.

As described above, the charge-discharge apparatus for the rechargeable battery 100 according to the first one or more embodiments of the present disclosure may measure the changing thickness of the battery cell 11 during the charging and discharging process of the battery cell 11 in real time by measuring the separation distance between the base plate 10 and the elevating plate 40 while the battery cell 11 is located between the base plate 10 and the elevating plate 40. In one or more embodiments, the reliability and lifespan of the battery cell 11 may be evaluated by checking the thickness change due to charging and discharging of the battery cell 11 in real time.

In one or more embodiments, the temperature-measuring part 60 for temperature measurement may be installed on the lower surface of the plate 40 where the battery cell 11 is in contact so that the changing temperature may be measured in real time while measuring the thickness of the battery cell 11, and it may be possible to evaluate the reliability and lifespan of the battery cell 11 more effectively.

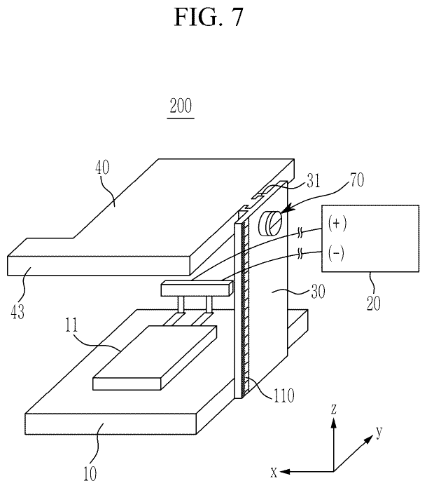

FIG. 7 is a perspective view schematically showing a charge-discharge apparatus for a rechargeable battery according to second one or more embodiments of the present disclosure. The same reference numbers as in FIGS. 1 to 6 refer to identical or similar members with the same or similar functions. Hereinafter, detailed descriptions of the same reference numbers will be omitted.

As shown in FIG. 7, a charge-discharge apparatus for a rechargeable battery 200 according to the second one or more embodiments of the present disclosure may display a distance display scale 110 on the side surface of the support part 30. The distance display scale 110 may be displayed in a long vertical direction on the side surface of the support part 30 to facilitate the operator's visual confirmation of the vertical movement of the elevating plate 40.

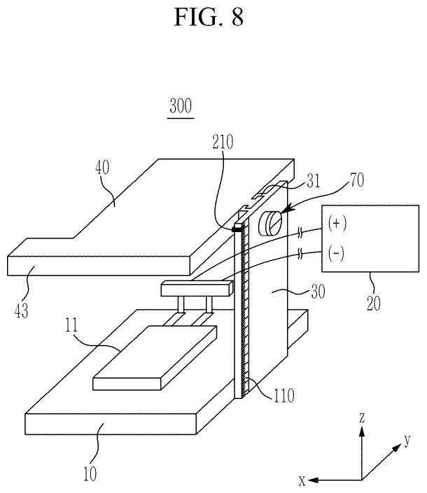

FIG. 8 is a perspective view schematically showing a charge-discharge apparatus for a rechargeable battery according to second one or more embodiments of the present disclosure. The same reference numbers as in FIGS. 1 to 7 refer to identical or similar members with the same or similar functions. Hereinafter, detailed descriptions of the same reference numbers will be omitted.

As shown in FIG. 8, the charge-discharge apparatus for the rechargeable battery 200 according to the third one or more embodiments of the present disclosure may have an indicator 210 protruding in the direction of the distance display scale 110 on the side surface of the elevating plate 40.

The indicator 210 may move together with the elevating plate 40, and may indicate the distance display scale 110, allowing the user to easily check the elevation movement of the elevating plate 40.

While this disclosure has been described in connection with what is presently considered to be practical embodiments, it is to be understood that the disclosure is not limited to the disclosed embodiments, but is intended to cover various modifications and equivalent arrangements included within the spirit and scope of the appended claims.

Description of Symbols 10: Base plate 11: Battery cell 20: Charger-discharger 30: Support part 31: Guide rail 40: Elevating plate 41: Insertion groove 50: Distance-measuring part 60: Temperature-measuring part, TC wire 70: Display part 71: Receiver 73: Display 73a: Distance display panel 73b: Temperature display panel 110: Distance display scale 210: Indicator

What is claimed is:

1. A charge-discharge apparatus for a rechargeable battery, comprising:
a base plate configured to have a battery cell affixed thereon;
a charger-discharger on the base plate, and configured to charge the battery cell;
a support part protruding from one side of the base plate;
an elevating plate at the support part, and configured raise and lower;
a distance-measuring part configured to measure a separation distance between the base plate and the elevating plate contacting the battery cell;
a temperature-measuring part at a lower surface of the elevating plate, and configured to measure a temperature of the battery cell; and
a display part configured to display the separation distance and the temperature.

2. The charge-discharge apparatus for the rechargeable battery as claimed in claim 1, further comprising a guide rail configured to guide the elevating plate at a side surface of the support part.

3. The charge-discharge apparatus for the rechargeable battery as claimed in claim 2, wherein the elevating plate is detachably at the support part.

4. The charge-discharge apparatus for the rechargeable battery as claimed in claim 3, further comprising a handle protruding from a side surface of the elevating plate.

5. The charge-discharge apparatus for the rechargeable battery as claimed in claim 4, wherein the elevating plate defines an insertion groove for receiving the temperature-measuring part.

6. The charge-discharge apparatus for the rechargeable battery as claimed in claim 5, wherein the insertion groove comprises a mesh shape at the lower surface of the elevating plate.

7. The charge-discharge apparatus for the rechargeable battery as claimed in claim 6, wherein the temperature-measuring part comprises a thermocouple (TC) wire inserted into the lower surface of the elevating plate.

8. The charge-discharge apparatus for the rechargeable battery as claimed in claim 7, wherein the temperature-measuring part comprises a mesh shape.

9. The charge-discharge apparatus for the rechargeable battery as claimed in claim 1, wherein the distance-measuring part comprises a laser sensor between the elevating plate and the base plate.

10. The charge-discharge apparatus for the rechargeable battery as claimed in claim 9, wherein the display part comprises:
a receiver configured to receive a sensing signal from the distance-measuring part or the temperature-measuring part; and
a display configured to display information corresponding to the sensing signal.

11. The charge-discharge apparatus for the rechargeable battery as claimed in claim 10, wherein the display comprises a distance display panel configured to display the separation distance.

12. The charge-discharge apparatus for the rechargeable battery as claimed in claim 11, wherein the display further comprises a temperature display panel configured to display the temperature of the battery cell.

13. The charge-discharge apparatus for the rechargeable battery as claimed in claim 1, further comprising a distance display scale at a side surface of the support part.

14. The charge-discharge apparatus for the rechargeable battery as claimed in claim 13, further comprising an indicator for indicating the distance display scale at a side surface of the elevating plate.
